(19) United States
(12) Patent Application Publication
(10) Pub. No.: US 2011/0109791 A1
(43) Pub. Date: May 12, 2011

(54) CERAMIC PACKAGE AND CAMERA MODULE

(75) Inventors: Takuro Obara, Kanagawa (JP); Toyokazu Aizawa, Kanagawa (JP); Hiromichi Kobayashi, Saitama (JP); Katsuo Iwata, Kanagawa (JP)

(73) Assignee: Kabushiki Kaisha Toshiba, Tokyo (JP)

(21) Appl. No.: 12/885,118

(22) Filed: Sep. 17, 2010

(30) Foreign Application Priority Data
Nov. 6, 2009 (JP) 2009-254949

(51) Int. Cl. H04N 5/225; H01L 31/0203

(52) U.S. Cl. 348/374; 257/433; 348/E05.024

(57) ABSTRACT

According to one embodiment, a ceramic package of which inner space is sealed by a ceramic base plate and a cover portion mounted on the ceramic base plate. The ceramic package has an image sensor, an element unit and a lead electrode. The image sensor and the element unit are mounted on the ceramic base plate. The lead electrode is formed on the ceramic base plate and electrically connected to the image sensor by a bonding wire. A surface on which the lead electrode is formed is the same as a surface on which the cover portion is mounted.

### CROSS-REFERENCE TO RELATED APPLICATIONS

This application is based upon and claims the benefit of priority from the prior Japanese Patent Application No. 2009-254949, filed on Nov. 6, 2009; the entire contents of which are incorporated herein by reference.

### FIELD

Embodiments described herein relate generally to a ceramic package and a camera module.

### BACKGROUND

A ceramic package in which an image sensor is mounted on a ceramic base plate obtained by laminating thin ceramic plates is used. Such a ceramic package is required to be made smaller while accommodating a passive element component and an active element component therein in addition to the image sensor.

### BRIEF DESCRIPTION OF THE DRAWINGS

FIG. 1 is a view illustrating a planar configuration of a ceramic package according to a first embodiment;

FIG. 2 is a cross-sectional view taken along line A-A of the ceramic package illustrated in FIG. 1 as seen in a direction indicated by an arrow;

FIG. 3 is a view illustrating a planar configuration of a conventional ceramic package as a comparative example;

FIG. 4 is a cross-sectional view taken along line B-B of the ceramic package illustrated in FIG. 3 as seen in a direction indicated by an arrow;

FIG. 5 is a view illustrating a planar configuration of the ceramic package according to a second embodiment;

FIG. 6 is a cross-sectional view taken along line C-C of the ceramic package illustrated in FIG. 5 as seen in a direction indicated by an arrow; and

FIG. 7 is a cross-sectional view of a camera module according to a third embodiment.

### DETAILED DESCRIPTION

In general, according to one embodiment, a ceramic package of which inner space is sealed by a ceramic base plate and a cover portion mounted on the ceramic base plate. The ceramic package has an image sensor, an element unit and a lead electrode. The image sensor and the element unit are mounted on the ceramic base plate. The lead electrode is formed on the ceramic base plate and electrically connected to the image sensor by a bonding wire. A surface on which the lead electrode is formed is the same as a surface on which the cover portion is mounted.

Exemplary embodiments of the ceramic package and a camera module will be explained below in detail with reference to the accompanying drawings. The present invention is not limited to the following embodiments.

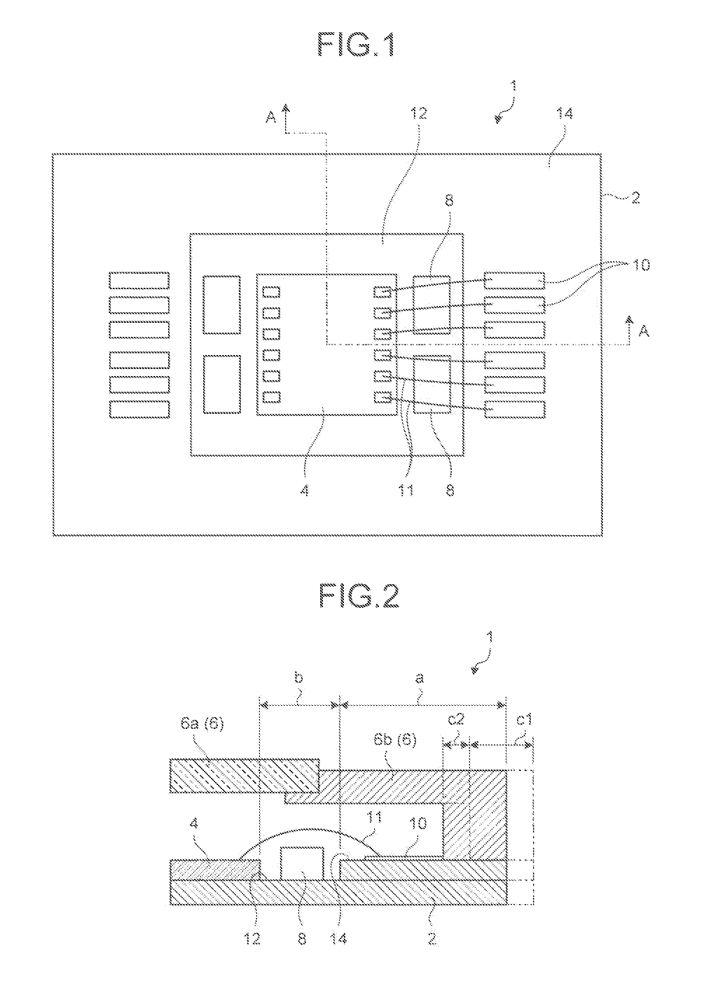

FIG. 1 is a view illustrating a planar configuration of the ceramic package according to a first embodiment of the present invention. FIG. 2 is a cross-reference view taken along line A-A of the ceramic package illustrated in FIG. 1 as seen in a direction indicated by an arrow. Meanwhile, the cover portion is not shown in FIG. 1.

The ceramic package 1 has a ceramic base plate 2, an image sensor 4, a cover portion 6, an element unit 8 and a lead electrode 10. The ceramic base plate 2 is obtained by laminating thin ceramic plates. The ceramic base plate 2 includes a first surface 12 and a second surface 14 formed at different levels as illustrated in FIG. 2. The image sensor 4 and the element unit 8 are mounted on the first surface 12. The lead electrode 10 is formed and the cover portion 6 is mounted on the second surface 14.

The image sensor 4 converts light from an object to a signal charge to obtain image data. The cover portion 6 is mounted on the ceramic base plate 2 so as to cover a surface thereof on a side of the first surface 12 and the second surface 14. The inner space to accommodate the image sensor 4 and the element unit 8 is sealed by the ceramic base plate 2 and the cover portion 6.

The cover portion 6 inhibits dust and the like from entering the inner space. The cover portion 6 includes a glass portion 6a and a resin portion 6b. Since the cover portion 6 includes a transparent glass portion 6a, the light from the object can reach the image sensor 4 without being interrupted by the cover portion 6. The cover portion 6 is mounted on the ceramic base plate 2 by adherence of the resin portion 6b to the second surface 14 of the ceramic base plate 2.

The element unit 8 is a passive element component or an active element component. As the passive element component, there are a capacitor, resistance and an inductor, for example. As the active element component, there are a driver IC for driving a lens actuator not shown and a nonvolatile memory, for example. The lead electrode 10 is formed on the second surface 14 of the ceramic base plate 2. The lead electrode 10 is formed by patterning of gold plating, for example. The lead electrode 10 is electrically connected to the image sensor 4 by a bonding wire 11.

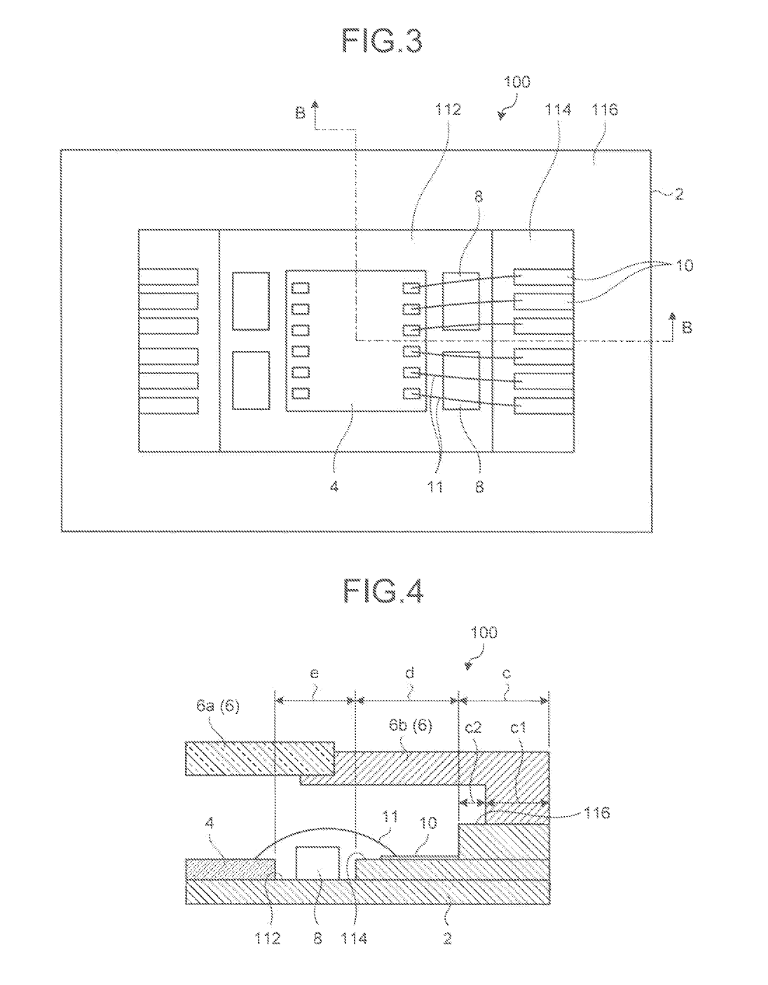

Next, a conventional ceramic package as a comparative example is illustrated in the drawing. FIG. 3 is a view illustrating a planar configuration of a conventional ceramic package 100 as the comparative example. FIG. 4 is a cross-sectional view taken along line B-B of the ceramic package 100 illustrated in FIG. 3 as seen in a direction indicated by an arrow. Meanwhile, in FIG. 3, the cover portion is not shown. As illustrated in FIG. 3, in the conventional ceramic package 100, the ceramic base plate 2 is often formed to have three different levels. The image sensor 4 and the element unit 8 are mounted on a first surface 112 and the lead electrode 10 is formed on a second surface 114. The cover portion 6 is mounted on a third surface 116 formed on a position higher than the second surface 114. Herein, a width of the third surface 116 of the ceramic base plate 2 described in the comparative example is set to “c”, a width of the second surface 114 thereof is set to “d” and a width between an end of the second surface 114 and the image sensor 4 is set to “e”.

The ceramic base plate 2 is obtained by laminating ceramic plates composing the first surface 112, the second surface 114 and the third surface 116. Each of the ceramic plates composing the second surface 114 and the third surface 116 is formed into a frame shape enclosing the first surface 112 in a planar view, and it is difficult to form the same to have a width narrower than a certain width in manufacturing the ceramic plate.

In the third surface 116, the width of the ceramic plate directly becomes the width of the third surface 116. Although the cover portion 6 can be mounted on the third surface 116 when the width thereof is not smaller than “c1”, this is formed to have the width larger than “c1” by “c2” due to limitation in manufacturing.

With reference to FIG. 2 again, in the ceramic package 1 according to the first embodiment, the ceramic base plate 2 is formed so as to have two different levels. Also, the cover portion 6 is mounted on the second surface 14 on which the lead electrode 10 is formed. That is to say, the surface on which the lead electrode 10 is formed is the same as the surface on which the cover portion 6 is mounted.

By configuring in this manner, a width “a” of the second surface 14 can be made smaller than “c+d”, which is the sum of the widths of the second surface 114 and the third surface 116, in the comparative example by approximately “c2”. According to this, an outer size of the ceramic package 1 can be made smaller than that of the ceramic package 100 illustrated in the comparative example by approximately “c2×2” including a reduced width on a side opposite to the side illustrated in FIG. 2.

In the conventional ceramic package 100 as the comparative example illustrated in FIGS. 3 and 4, as for the width “d” of the second surface 114, a certain width is required for the patterning of the lead electrode 10. On the other hand, in the first embodiment, the second surface 14 is formed to have the width “a” larger than the width of the second surface 114 of the comparative example such that the cover portion 6 can also be mounted thereon. Therefore, it is easy to secure a sufficient size for the patterning of the lead electrode 10, so that the width corresponding to the width “d” in the comparative example can be made smaller in the first embodiment. According to the same, the ceramic package 1 can be made further smaller.

Laminating steps can be reduced by laminating the ceramic plates to have the two different levels than to have the three different levels. According to the same, laminating tolerance, which is generated when laminating the ceramic plates, can be reduced and the ceramic package 1 can be made further smaller.

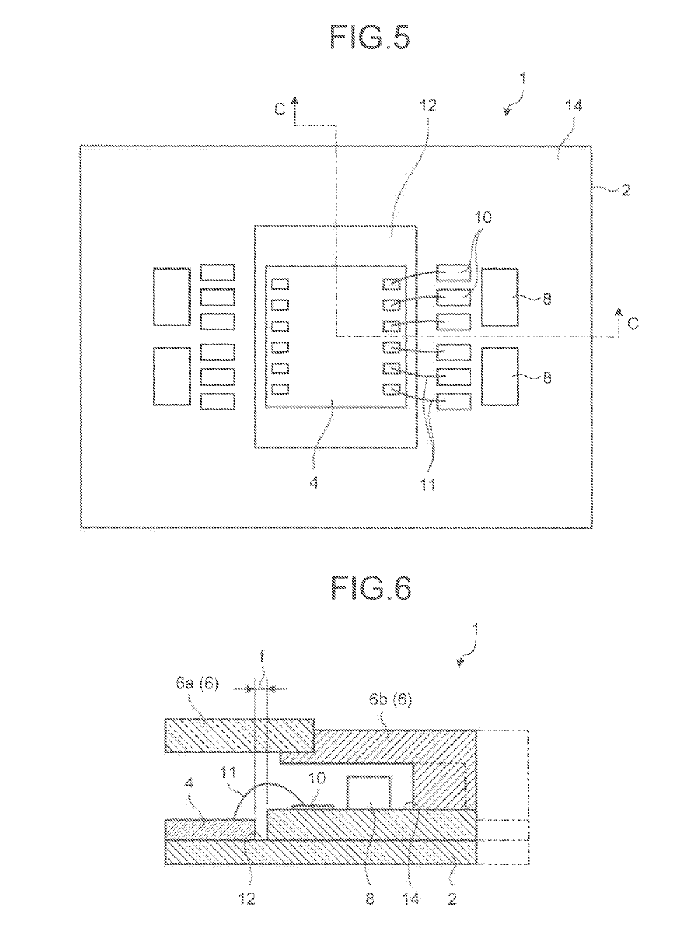

FIG. 5 is a view illustrating a planar configuration of the ceramic package according to a second embodiment. FIG. 6 is a cross-sectional view taken along line C-C of the ceramic package illustrated in FIG. 5 as seen in a direction indicated by an arrow. Meanwhile, the cover portion is not shown in FIG. 5.

In the second embodiment, as in the first embodiment, the ceramic base plate 2 is formed to have the two different levels. However, in the second embodiment, the element unit 8 is mounted on the second surface 14. Also, the element unit 8 is mounted on a position deviated from an area between the image sensor 4 and the lead electrode 10 connected to each other by the bonding wire 11.

Herein, since the element unit 8 is mounted on the first surface 112 in the conventional ceramic package 100 as the comparative example illustrated in FIGS. 3 and 4, a predetermined space is formed between the image sensor 4 and the element unit 8 and between the ceramic plate composing the second surface 114 and the element unit 8. By the spaces formed on both sides of the element unit 8, workability when mounting the element unit 8 and the like is secured. That is to say, the width “e” is the sum of the width of the element unit 8 and the widths of the spaces formed on the both sides thereof.

On the other hand, in the second embodiment, since the element unit 8 is mounted on the second surface 14, a width “f” of a part corresponding to the width “e” can be made smaller. Also, there is no step and wall surface on the both sides of the element unit 8 before mounting the cover portion 6, so that the workability when mounting the element unit 8 can be secured without considering the spaces on the both sides of the element unit 8. Therefore, the spaces formed on the both sides of the element unit 8 can be reduced and the ceramic package 1 can be made further smaller.

Unlike the second embodiment, when mounting the element unit 8 in the area between the image sensor 4 and the lead electrode 10, there is a following problem. That is to say, when mounting the element unit 8 in the area between the image sensor 4 and the lead electrode 10, it is required to allow the bonding wire 11 to pass above the element unit 8, so that the bonding wire 11 and the element unit 8 might interfere with each other and a defect might occur. On the other hand, in the second embodiment, the element unit 8 is mounted on the second surface 14 and on a position deviated from the area between the image sensor 4 and the lead electrode 10, so that the bonding wire 11 and the element unit 8 hardly interfere with each other and the above-described defect can be inhibited from occurring. Meanwhile, in the first embodiment, since the element unit 8 is mounted on the first surface 12 lower than the second surface 14 by one level, the problem of interference hardly occurs even when the bonding wire 11 is allowed to pass above the element unit 8.

Meanwhile, although the ceramic base plate 2 is formed to have the two different levels in the above-described embodiment, this may be formed without different levels. For example, in a case in which the image sensor 4, the element unit 8, the lead electrode 10 and the cover portion 6 are mounted on the same surface also, a problem of a required size in manufacturing required for the third surface 116 in the comparative example can be resolved. Therefore, when the ceramic base plate is formed without different levels also, the ceramic package can be made smaller than in a case in which the ceramic base plate is formed to have the three different levels as in the comparative example. The laminating steps of the ceramic plate can also be further reduced, so that the ceramic package can be made further smaller by reducing the laminating tolerance.

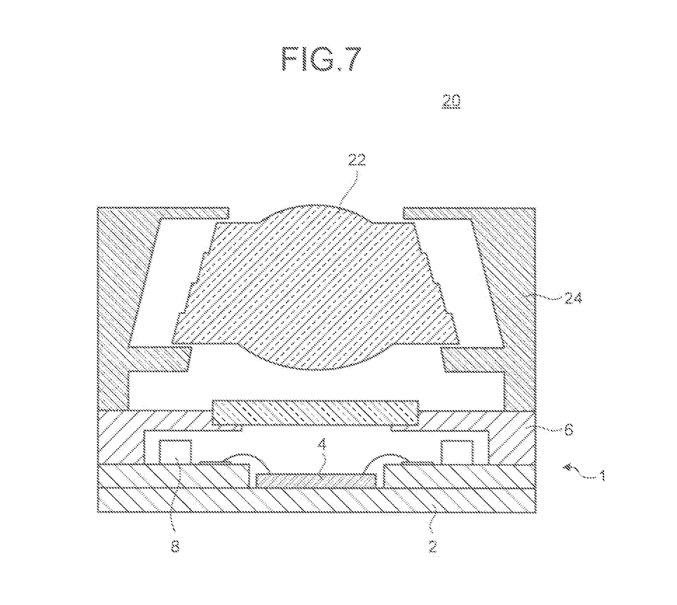

FIG. 7 is a cross-sectional view of the camera module according to a third embodiment. A camera module 20 is for taking an image of the object. The camera module 20 has the ceramic package 1 described in the above-described second embodiment, an optical lens 22 and a lens actuator 24. The optical lens 22 is arranged on a side of the cover portion 6 of the ceramic package 1. The optical lens 22 takes the light from the object and allows the same to travel toward the image sensor 4. The optical lens 22 may be composed as a lens unit in which a plurality of lenses are combined or composed of a single lens.

The lens actuator 24 supports the optical lens 22. The lens actuator 24 drives the optical lens 22 based on an instruction from controlling means not shown and the element unit 8 to adjust a focal point of the optical lens 22. Meanwhile, a detailed description of a drive mechanism for driving the optical lens 22 is omitted.

As described in the second embodiment, the camera module 20 itself can be made smaller by making the ceramic package 1 smaller.

Meanwhile, although the camera module 20 is described to include the ceramic package 1 described in the second embodiment, this may include the ceramic package 1 described in the first embodiment, of course.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A ceramic package of which inner space is sealed by a ceramic base plate and a cover portion mounted on the ceramic base plate, comprising:
an image sensor mounted on the ceramic base plate in the inner space;
an element unit mounted on the ceramic base plate in the inner space; and
a lead electrode formed on the ceramic base plate in the inner space and electrically connected to the image sensor by a bonding wire, wherein
a surface on which the lead electrode is formed is the same as a surface on which the cover portion is mounted.

2. The ceramic package according to claim 1, wherein
the surface on which the lead electrode is formed and a surface on which the image sensor is mounted are formed at different levels.

3. The ceramic package according to claim 1, wherein
the surface on which the lead electrode is formed is the same as a surface on which the element unit is mounted.

4. The ceramic package according to claim 1, wherein
the surface on which the lead electrode is mounted is the same as a surface on which the image sensor is mounted and a surface on which the element unit is mounted.

5. The ceramic package according to claim 1, wherein
the cover portion includes a transparent area.

6. The ceramic package according to claim 1, wherein
the element unit is a passive element component.

7. The ceramic package according to claim 1, wherein
the element unit is an active element component.

8. The ceramic package according to claim 1, wherein
the lead electrode is formed by patterning of gold plating on the ceramic base plate.

9. The ceramic package according to claim 3, wherein
the element unit is mounted on a position deviated from an area between the image sensor and the lead electrode.

10. A camera module, comprising:
a ceramic package of which inner space is sealed by a ceramic base plate and a cover portion mounted on the ceramic base plate, the ceramic package including an image sensor mounted on the ceramic base plate in the inner space, an element unit mounted on the ceramic base plate in the inner space, and a lead electrode formed on the ceramic base plate in the inner space and electrically connected to the image sensor by a bonding wire in which a surface on which the lead electrode is formed is the same as a surface on which the cover portion is mounted;
an optical lens that allows light from an object to travel toward the image sensor; and
a lens actuator that drives the optical lens.

11. The camera module according to claim 10, wherein
the surface on which the lead electrode is formed and a surface on which the image sensor is mounted are formed at different levels.

12. The camera module according to claim 10, wherein
the surface on which the lead electrode is formed is the same as a surface on which the element unit is formed.

13. The camera module according to claim 10, wherein
the surface on which the lead electrode is mounted is the same as a surface on which the image sensor is mounted and a surface on which the element unit is mounted.

14. The camera module according to claim 10, wherein
the cover portion includes a transparent area.

15. The camera module according to claim 10, wherein
the lead electrode is formed by patterning of gold plating on the ceramic base plate.

16. The camera module according to claim 12, wherein
the element unit is mounted on a position deviated from an area between the image sensor and the lead electrode.
